(19) United States
(12) Patent Application Publication
(10) Pub. No.: US 2018/0212089 A1
(43) Pub. Date: Jul. 26, 2018

(54) BACK SHEET FOR SOLAR CELL MODULE AND SOLAR CELL MODULE MADE THEREOF

(71) Applicant: E I DU PONT DE NEMOURS AND COMPANY, Wilmington, DE (US)

(72) Inventors: Peng Li, Shanghai (CN); Shuang Wu, Shanghai (CN)

(21) Appl. No.: 15/878,826

(22) Filed: Jan. 24, 2018

(30) Foreign Application Priority Data
Jan. 25, 2017 (CN) 20170060837.9

(51) Int. Cl. H01L 31/049; H01L 31/0224; H01L 31/05

(52) U.S. Cl. CPC H01L 31/049; H01L 31/05; H01L 31/022441

(57) ABSTRACT

Disclosed herein is a back sheet comprising a substrate comprising a silane crosslinked polyethylene composition, an adhesive layer, and a weather resistant layer. Also, disclosed herein are solar cell modules made thereof and methods for manufacturing the back sheet.

### BACKGROUND INFORMATION

### Field of the Disclosure

The present invention relates to a solar cell module back sheet comprising a silane cross-linked polyethylene composition, a solar cell module manufactured from the back sheet, and a method for manufacturing the back sheet.

### Description of the Related Art

A solar cell generates electricity from sunlight, which provides an environmentally friendly alternative method to traditional electricity generation methods. In general, a plurality of solar cells can be electrically connected to form an array, and such an array can be connected together in a single installation to provide a desired amount of electricity; an electrically connected solar cell array is generally encapsulated with a front encapsulating material and a back encapsulating material, and the encapsulated module array is further sandwiched between transparent front and back sheets to manufacture a solar cell module. The back sheet of the solar cell module can serve as a support and withstand the environment. Back sheets widely used in the prior art are generally multi-layer structures comprising a fluorine material, e.g., ethylene vinyl acetate copolymer/polyethylene terephthalate/polyvinyl fluoride (EVA/PET/PVF) or polyvinyl fluoride/polyethylene terephthalate/polyvinyl fluoride (PVF/PET/PVF), in which there is also an adhesive layer between adjacent layers to increase the bonding strength therebetween. The disadvantage of such a back sheet is that applying the adhesive many times and then compounding are required in the preparation process, the preparation process being complicated and costly. Moreover, since polyethylene terephthalate (PET) has a high material cost and the mechanical properties thereof deteriorate with time, that is, the aging resistance is poor, the solar cell module will eventually fail. It has been proposed that a cross-linked polyethylene film may be used in the back sheet of a solar cell module to enhance the aging resistance of the back sheet; however, cross-linked polyethylene tends to generate a large number of holes during film formation, and the use of polyethylene in the back sheet causes the water resistance, electrical insulation and mechanical properties of the back sheet to all be poorer. Therefore, there is still a need to develop a back sheet that is prepared by simple preparation steps, has lower material and manufacturing costs, and has excellent mechanical properties, water resistance and electrical insulation.

### SUMMARY

The present invention provides a solar cell module back sheet, comprising:

(i) a substrate comprising a silane crosslinked polyethylene composition;

(ii) an adhesive layer comprising a polyurethane; and

(iii) a weather resistant layer comprising a fluoropolymer;

wherein:

the weather resistant layer (iii) has a front surface and a back surface, the front surface faces towards a light source when in use;

the adhesive layer (ii) is in contact with the substrate (i) and the front surface of the weather resistant layer (iii); and

the silane crosslinked polyethylene composition is derived from the reaction of components (a), (b), (c), (d), (e) and (f) as follows:
(a) 60 to 98.74 wt % of a polyethylene selected from the group consisting of linear low density polyethylene, high density polyethylene, low density polyethylene, and blends thereof;
(b) 0.1 to 2.5 wt % of a silane;
(c) 1 to 3 wt % of a titanium dioxide;
(d) 0.05 to 0.5 wt % of a peroxide;
(e) 0.01 to 0.05 wt % of a carboxylate of tin; and
(f) 0.1 to 33.95 wt % of at least one additive selected from the group consisting of inorganic fillers excluding titanium dioxide, anti-oxidant agents, anti-UV agents, lubricants, and mixtures thereof;

wherein the wt % is based on the total weight of the combined components.

The present invention further provides a solar cell module comprising at least one solar cell having a front surface and a back surface, a back encapsulant layer, and the back sheet above, wherein the back encapsulant layer is in contact with the back surface of the solar cell and the substrate (i) of the back sheet; and the front surface of solar cell faces towards a light source when in use.

The present invention further provides a method for manufacturing a back sheet for a solar cell module comprising:

(1) providing a layer comprising a fluoropolymer as a weather resistant layer, which has a front surface and a back surface;

(2) applying a layer comprising a polyurethane to the front surface of the weather resistant layer to obtain an adhesive layer;

(3) providing components (a), (b), (c), (d), (e), and (f) as follows:
(a) 60 to 98.74 wt % of a polyethylene selected from the group consisting of linear low density polyethylene, high density polyethylene, low density polyethylene, and blends thereof;
(b) 0.1- to 2.5 wt % of a silane;
(c) 1 to 3 wt % of a titanium dioxide;
(d) 0.05 to 0.5 wt % of a peroxide;
(e) 0.01 to 0.05 wt % of a carboxylate of tin; and
(f) 0.1 to 33.95 wt % of at least one additive selected from the group consisting of glass fibers, talcs, silica dioxides, micas, zinc sulfides, calcium carbonates, boron nitrides, clays, anti-oxidant agents, anti-UV agents, lubricants, and mixtures thereof;

wherein the wt % is based on the total weight of the combined components; (4) blending the components (a), (b), (c), (d), (e) and (f) at a temperature of 180 to 230° C. to obtain a blend;

(5) casting the blend of Step (4) to obtain a sheet comprising a silane crosslinked polyethylene composition; and

(6) laminating the sheet comprising a silane crosslinked polyethylene composition on top of the adhesive layer to obtain the back sheet.

### BRIEF DESCRIPTION OF THE DRAWINGS

FIG. 1 shows an expanded side view of one embodiment of the solar cell module back sheet 100 of the present invention, the back sheet comprising, in order: (i) a substrate 11, (ii) an adhesive layer 12 and (iii) a weather-resistant layer 13, wherein the weather-resistant layer has a front surface 131 facing solar radiation and a back surface 132 not facing the solar radiation when in use, and the adhesive layer 12 is bonded to the front surface 131 of the weather-resistant layer and the substrate 11.

FIG. 2 shows an expanded side view of one embodiment of the solar cell module 200 of the present invention, the solar cell module comprising, in order: a front sheet 21, a front encapsulant layer 22, solar cells 23, solder strips 24, a back encapsulant layer 25 and a back sheet 100, the solar cell 23 having a front surface 231 facing solar radiation and a back surface 232 not facing the solar radiation when in use, and the back encapsulant layer being bonded to the back surface 232 of the solar cell and a substrate 11 of the back sheet 100.

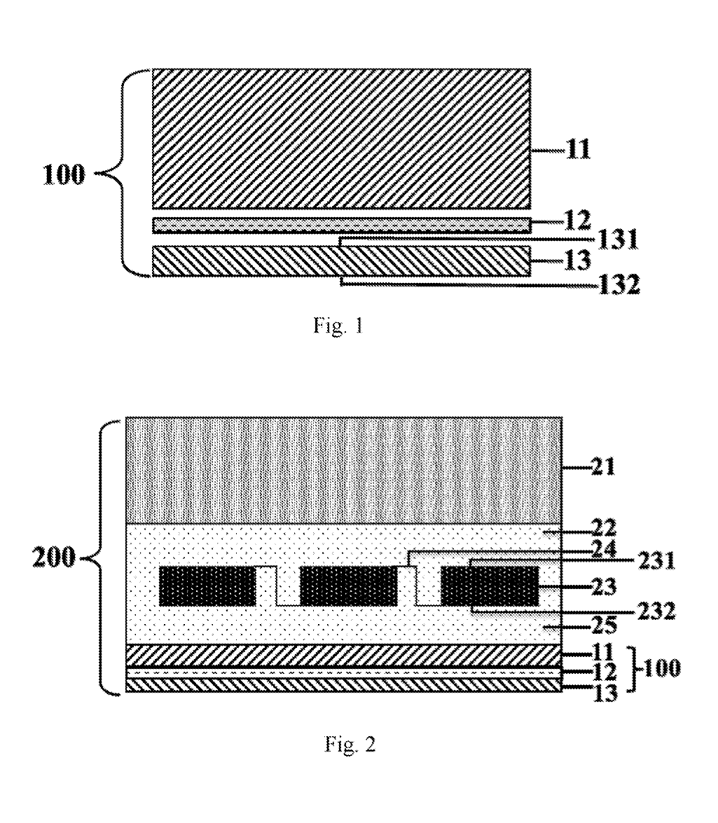

### DETAILED DESCRIPTION

Unless otherwise indicated, all publications, patent applications, patents, and other reference documents mentioned herein are expressly incorporated in their entirety herein by reference as though they are fully disclosed herein.

Unless otherwise defined, all technical and scientific terms used herein have the same meaning as commonly understood by a person skilled in the art to which the present invention belongs. In the case of conflict, the definitions in this specification shall prevail.

Unless otherwise indicated, all percentages, parts, ratios, etc., are by weight.

The term “prepared from . . . ” herein is equivalent to “comprise”. As used herein, the terms “comprises/comprising”, “includes/including”, “has/having” or “contains/containing”, or any other variations thereof, are intended to cover non-exclusive inclusion. For example, a composition, process, method, article or apparatus which comprises a series of elements is not limited only to these elements but may further include other elements not expressly listed in or inherent to such a composition, process, method, article or apparatus.

The phrase “consisting of . . . ” does not include any element, step or component which is not expressly listed. If in a claim, the phrase limits the claim to described materials without comprising any material that is not described, but still comprises impurities generally associated with those described materials. Where the phrase “consisting of . . . ” appears in the characterizing portion of a claim, rather than in the immediate preamble, it merely limits the elements as described in the characterizing portion, while other elements are not excluded from this claim in its entirety.

The phrase “consisting essentially of . . . ” is used to define a composition, method or apparatus that further comprises additional materials, steps, features, components or elements in addition to those materials, steps, features, components or elements as described literally, provided that these additional materials, steps, features, components or elements do not substantively affect the basic and novel features of the claimed invention. The term “consisting essentially of . . . ” is between “comprising” and “consisting of . . . ”.

The term “comprising” is intended to include the embodiments encompassed by the terms “consisting essentially of . . . ” and “consisting of . . . ”. Similarly, the term “consisting essentially of” is intended to include the embodiments encompassed by the term “consisting of . . . ”.

The term “excluding” a component/components indicates that the component/components should comprise less than 0.1 wt %, preferably 0 wt %, relative to the total weight of the inorganic filler excluding titanium oxide.

When numbers, concentrations, or other numerical values or parameters are given as ranges, preferred ranges, or a series of upper and lower preferred values, this is to be understood as explicitly disclosing all ranges formed by any pair of any upper range limit or preferred value and any lower range limit or preferred value, regardless of whether the ranges are disclosed separately or not. For example, when describing a range of “1 to 5”, the range should be construed as including the ranges of “1 to 4”, “1 to 3”, “1 to 2”, “1 to 2 and 4 to 5”, “1 to 3 and 5”, etc. Where reference is made to a range of numerical values, the range is intended to include the endpoints thereof and all integers and fractions within the range, unless otherwise indicated.

Where the term “about” is used to describe a value or a range endpoint value, the disclosed contents should be understood as including the specific value or endpoint value mentioned.

Moreover, the term “or” indicates that the “or” is inclusive rather than exclusive, unless expressly stated to the contrary. For example, condition A “or” B satisfies any one of the following: A is true (or present) and B is false (or not present), A is false (or not present) and B is true (or present), and A and B are both true (or present).

The term “layer” herein describes an overall planar arrangement of a polymer film or sheet. The term “film” or “sheet” as used interchangeably herein refers to a continuous thin, flat structure having a uniform thickness. The term “plane of a film or sheet” herein refers to a continuous thin, flat structure having a uniform thickness. In general, a sheet may have a thickness of greater than about 100 μm and a film may have a thickness of about 100 μm or less.

The embodiments of the present invention described in the summary of the invention, including any other embodiments described herein, may be combined in any manner, and the description of the variables in the embodiments is not only suitable for the back sheet of the present invention but also for a solar cell module manufactured therefrom.

The present invention is described in detail below.

### Substrate

In the present invention, the substrate (i) comprises a silane cross-linked polyethylene composition, and has a thickness of about 100 μm to 500 μm, or about 150 μm to 450 μm, or about 200 μm to 350 μm. The substrate or plane of the sheet of the silane cross-linked polyethylene composition has zero or not greater than 15, not greater than 10, not greater than 5, or not greater than 3 holes per 100 m² of area, and herein, a penetrable hollow with an area of greater than 0.01 cm² formed on the plane thereof due to the lack of silane cross-linked polyethylene is considered a hole.

The silane cross-linked polyethylene composition for use in the substrate (i) of the present invention refers to a polyethylene formed as a cross-linked network structure by introducing a silane, which composition can be obtained by reacting components (a), (b), (c), (d), (e) and (f) below:

(a) about 60 wt % to 98.74 wt % of a polyethylene selected from a linear low density polyethylene (LLDPE), a low density polyethylene (LDPE), a high density polyethylene (HDPE), and a mixture thereof;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 33.95 wt % of at least one additive selected from an inorganic filler excluding titanium oxide, an antioxidant, an anti-ultraviolet agent, a lubricant, and a mixture thereof,

wherein the wt % is based on the total weight of the components (a), (b), (c), (d), (e) and (f).

A polyethylene (a) suitable for the present invention may be selected from LLDPE, LDPE, HDPE, and a mixture thereof. The polyethylene is formed by the addition polymerization of ethylene, wherein the LLDPE is produced by copolymerizing some copolymers having a short-chain branch in the backbone of a polyethylene and has a density of about 0.915 g/cm³ to 0.925 g/cm³; the LDPE is produced by free radical polymerization at a high temperature and a high pressure, has many branches in the molecular chain thereof and has a density of about 0.910 g/cm³ to 0.940 g/cm³; and the HDPE is usually produced by using a Ziegler-Natta catalyst polymerization method, with the molecular chain thereof being arranged regularly and substantially having no branch, and the density thereof is greater than or equal to about 0.941 g/cm³. In one embodiment, the polyethylene used in the present invention is LLDPE. In another embodiment, the polyethylene used in the present invention is HDPE.

The polyethylene, as used herein, is commercially available. For example, commercially available LLDPEs include, but are not limited to, GS707™ available from Lyondell Chemical Company, LLDPE LL 1002YB and LLDPE LL 6201XR available from ExxonMobil, and LL0220AA available from Shanghai SECCO Petrochemical Company Limited; commercially available LDPEs include, but are not limited to, LDPE LD 654 available from ExxonMobil, and LDPE LD 654 available from CNOOC and Shell Petrochemicals Company Limited; and commercially available HDPEs include, but are not limited to, CONTINUUM™ and UNIVAL™ available from Dow Chemical, BS2581 available from Borealis, HostalenACP 5831D available from Lyondell/Basell, HD5502S available from Ineos, B5823 and B5421 available from Sabic, HDPE 5802 and BM593 available from Total, and HD5502FA available from Shanghai SECCO Petrochemical Company Limited.

Silanes (b) suitable for the present invention may be silanes containing graftable vinyl and hydrolyzable alkoxy, acyloxy, amino or chlorine-containing functional groups. In one embodiment, the silane used in the present invention is selected from vinyltrimethoxysilane (VTMS), vinyltriethoxysilane (VTES), vinyltris(2-methoxyethoxy)silane (VTMES), 3-methacryloyloxypropyltrimethoxy-silane (VMMS), and a mixture thereof. In another embodiment, the silane used in the present invention is VTES.

The silane, as used herein, is commercially available, for example, Geniosil GF58 available from Wacker Group, A-171 and A-151 under Silquest™ available from Momentive Performance Materials, or KBM-1003 and KBE-1003 available from Shin-Etsu Chemical Co., Ltd.

A peroxide (c) suitable for the present invention serves as an initiator which generates free radicals by thermal decomposition to extract hydrogen atoms on the molecular chain of the polyethylene, and the resulting polyethylene macromolecular chain free radicals undergo a grafting reaction with a double bond in silane molecules; and a peroxide (c) suitable for the present invention is preferably an organic peroxide which may be selected from dicumyl peroxide, benzoyl peroxide, t-butyl cumyl peroxide, di-t-butyl peroxide, and a mixture thereof. In one embodiment, the peroxide used in the present invention is dicumyl peroxide.

A tin carboxylate (d) suitable for the present invention serves as a catalyst, and can be selected from dibutyltin dilaurate, dibutyltin laurate maleate, di-n-butyltin, stannous octoate, dibutyltin diacetate, and a mixture thereof. In one embodiment, the tin carboxylate used in the present invention is dibutyltin dilaurate.

The shape of titanium oxide (e) suitable for the present invention is also not limited in any way, and may be spherical, polygonal, or irregular block-shaped, preferably spherical; a suitable spherical titanium oxide has an average particle size of about 0.05 μm to 5 μm, or 0.05 μm to 1 μm, or about 0.05 μm to 0.29 μm. The crystal form of the titanium oxide may be Anatase type (abbreviated to A type) and Rutile type (abbreviated to R type). The titanium oxide further comprises impurities of other components, such as aluminum oxide or silicon dioxide, wherein the content of titanium oxide is greater than 90%, preferably greater than 92%.

According to requirements, the titanium oxide may be added directly, or may also be subjected to a surface treatment (e.g., a treatment with a silane coupling agent) according to a method well known in the art. These techniques would be obvious to a person skilled in the art and will not be repeated here.

Glass fibers suitable for the present invention are commercially available, for example, Ti-Pure™ R-105 available from Chemours.

At least one additive (f) suitable for the present invention may be selected from an inorganic filler excluding titanium oxide, an antioxidant, an anti-ultraviolet agent, a lubricant, and a mixture thereof. Appropriate amounts of these additives and methods for incorporating these additives into a polymer composition are known to a person skilled in the art. Reference can be made to, for example, Modern Plastics Encyclopedia Handbook (McGraw-Hill, 1994).

According to the present invention, the inorganic filler excluding titanium oxide may be selected from glass fibers, talc, silicon dioxide, mica, zinc sulfide, calcium carbonate, boron nitride, clay, and a mixture thereof.

In one embodiment, the inorganic filler excluding titanium oxide in the solar cell module back sheet of the present invention is selected from glass fibers, talc, silicon dioxide, and a mixture thereof, and the content of the inorganic filler excluding titanium oxide is about 3 wt % to 33 wt %, the wt % being based on the total weight of the components (a), (b), (c), (d), (e) and (f).

Glass fibers suitable for the present invention may be ground glass fibers having an average diameter of about 0.05 μm to 30 μm and an average length of less than 100 μm. Glass fibers suitable for the present invention are commercially available, for example, EMG13-70C available from China Jushi Group Co., Ltd., EMG10-35, EMG10-70, EMG13-70C or EMG17-200C available from Taishan Fiberglass Inc.

In one embodiment, the amount of the glass fibers is about 3 wt % to 33 wt %, or about 3 wt % to 18 wt %, or 5 wt % to 15 wt %, wherein the wt % is based on the total weight of the components (a), (b), (c), (d), (e) and (f).

Talc suitable for the present invention is a talc powder having an average particle size of less than about 1000 mesh, or less than about 5000 mesh. Talc suitable for the present invention is commercially available, for example, HTP2, HM4, HTP05, HTP ultra 5L or HTP ultra 5C available from IMI FABI, and Finntalc M10E, Finntalc M03, Finntalc MO5SL or Finntalc M15 available from Mondo Minerals.

In one embodiment, the amount of the talc is about 3 wt % to 33 wt %, or about 8 wt % to 25 wt %, or about 10 wt % to 20 wt %, wherein the wt % is based on the total weight of the components (a), (b), (c), (d), (e) and (f).

Silicon dioxide suitable for the present invention is a spherical silicon dioxide having an average particle size of about 5 μm to 100 μm, or about 5 μm to 20 μm. Silicon dioxide suitable for the present invention is commercially available, for example, FB-15D, FB-975FD, FB-105FD or FB-970FD available from Denka Group, Japan, and FEB-75A, FED-75A or SC-250G available from Adamatechs.

In one embodiment, the amount of the silicon dioxide is about 3 wt % to 33 wt %, or about 15 wt % to 32 wt %, or about 20 wt % to 30 wt %, wherein the wt % is based on the total weight of the components (a), (b), (c), (d), (e) and (f).

According to requirements, the inorganic filler excluding titanium oxide may be subjected to a surface treatment using a method known in the art so as to increase the adhesion or compatibility thereof with the polymer. These techniques would be obvious to a person skilled in the art and will not be repeated here.

Suitable anti-ultraviolet agents and antioxidants include, but are not limited to, hindered phenolic compounds including, for example, tetrakis(methylene(3,5-di(tert)butyl-4-hydroxyhydrocinnamate))methane under the trade names Irganox® 1010 and Irganox® 1076, and poly(4-hydroxy-2,2,6,6-tetramethyl-1-piperidineethanol)succinate under the trade name Tinuvin™ 622, both available from BASF. Other suitable antioxidants include phosphorous acid salts or esters, e.g., ULTRANOX 626 and Westin® 619 sold by GE Specialty Chemical (Morgantown, W. Va., USA). Irgafos® 168 (tris(2,4-di-tert-butylphenyl)phosphite) sold by BASF is a common heat stabilizer and is commonly used as an auxiliary antioxidant.

Suitable lubricants include, but are not limited to, fluoropolymers, the monomers of which are primarily tetrafluoroethylene, ethylene, hexafluoropropylene, propylene, vinyl fluoride, and vinylidene fluoride. Lubricants used for the present invention are commercially available, for example, Viton™ Freeflow Z200 and Viton™ Freeflow Z210 sold by Chemours, Loxiol P861/3.5 and Loxiol PTS HOB 7119 sold by Cognis, and Licomont ET 132, Licomont ET141 and Licomont wax OP sold by Clariant Corp.

The silane cross-linked polyethylene composition for use in the present invention can be prepared by reacting the above-mentioned components (a), (b), (c), (d), (e) and (f), and the method therefor may be known to a person skilled in the art, e.g., a Sioplas method, a Monosil method, or other improved methods. The Sioplas method is a two-step method, comprising: first separately extruding a polyethylene silane grafting material and a catalytic masterbatch beforehand using two extruders, and then mixing the two materials in proportion and extruding same on an extruder to obtain a silane cross-linked polyethylene composition. The Monosil method is a one-step method, comprising: directly adding a polyethylene, a silane, a peroxide, a tin carboxylate, etc., into the same extruder and extruding same to obtain a silane cross-linked polyethylene composition. In one embodiment, a polyethylene, titanium oxide, an antioxidant, an anti-ultraviolet agent and a lubricant are uniformly mixed, put into an extruder, melt-extruded and pelletized to form a first masterbatch; the polyethylene is further mixed uniformly with another inorganic filler, etc., put into an extruder, melt-extruded and pelletized to form a second masterbatch; and then the above-mentioned two masterbatches, a polyethylene, a silane, a peroxide, a catalyst, etc., are mixed uniformly, put into an extruder and melt-extruded to obtain a silane cross-linked polyethylene composition.

The sheet comprising the silane cross-linked polyethylene composition can be prepared by means of a casting method when melt-extruding the above-mentioned silane cross-linked polyethylene composition. In one embodiment, the silane cross-linked polyethylene composition prepared by reacting the above-mentioned components (a), (b), (c), (d), (e) and (f), during melt-extrusion in an extruder, is extruded through a molding die of a T-shaped structure, and cast in a sheet form onto a roller surface of a cooling roller which is rotating smoothly, and the resulting sheet is shaped on the cooling roller through cooling, and further subjected to pulling and edge cutting to prepare the sheet comprising the silane cross-linked polyethylene composition.

### Adhesive Layer

In the present invention, the adhesive layer (ii) has a thickness of about 5 μm to 20 μm, or about 10 μm to 15 μm, and can be prepared from an adhesive comprising a polyurethane, preferably from a two-component polyurethane adhesive. The two-component polyurethane adhesive consists of two components A and B, wherein component A (a main component) is an active hydrogen-containing component, i.e., a polyurethane polyol, such as polyethylene glycol, polyether polyol or polybutylene glycol; and component B (a curing agent) is an —NCO group-containing polyurethane prepolymer, i.e., a polyisocyanate, which may be an aromatic diisocyanate such as toluene diisocyanate or diphenylmethane diisocyanate, or may also be an aliphatic diisocyanate such as hexamethylene diisocyanate, or isophorone diisocyanate.

The two-component polyurethane adhesive used for the present invention is commercially available, for example, Liofol LA 2525-21/UR 7397 available from Henkel, and CA022/TSH900 available from Dainippon Ink and Chemicals (DIC).

In the present invention, the adhesive layer may further comprise other common additives such as an antioxidant, a UV stabilizer, an anti-hydrolysis agent, a flame retardant, a pigment, a coupling agent, a hindered amine stabilizer and other additives, as long as the additive does not affect the bonding property and can bond the substrate (i) and the weather-resistant layer (iii).

The raw materials and molecular weights of the two components of the two-component polyurethane adhesive can generally be adjusted so that there is an appropriate viscosity thereunder, and the two components are mixed with a solvent such as ethyl acetate to form an adhesive composition, and then applied to the weather-resistant layer (iii) to prepare the adhesive layer in an application method including, but not limited to, roll coating, blade coating, or spray coating.

### Weather-Resistant Layer

In the present invention, the fluoropolymer comprised in the weather-resistant layer (iii) may be selected from homopolymers and copolymers of vinyl fluoride (VF), vinylidene fluoride (VDF), tetrafluoroethylene (TFE), hexafluoropropylene (HFP), and chlorotrifluoroethylene (CTFE), and combinations of two or more thereof. More specific exemplary fluoropolymers for use herein include, but are not limited to, polyvinyl fluoride (PVF), polyvinylidene fluoride (PVDF), an ethylene/chlorotrifluoroethylene copolymer (ECTFE), an ethylene/tetrafluoroethylene copolymer (ETFE), and combinations of two or more thereof. In one embodiment, the fluoropolymer may be selected from PVF, PVDF, and combinations thereof. In another embodiment, the fluoropolymer is PVF.

In the present invention, the weather-resistant layer (iii) is a film or sheet comprising a fluoropolymer, and has a thickness of about 5 μm to 50 μm, or about 10 μm to 40 μm, or about 15 μm to 30 μm. The film or sheet consisting of the fluoropolymer may be stretched or unstretched, preferably stretched.

As used herein, the term “stretched” refers to a stretching process in which the polymer film or sheet is uniaxially or biaxially stretched transversely and/or longitudinally to achieve a combination of mechanical and physical properties. A stretching apparatus and method for obtaining a uniaxially or biaxially stretched film or sheet are known in the art, and a person skilled in the art would have been able to appropriately modify the method to prepare the film or sheet comprising the fluoropolymer, as disclosed herein. Examples of the apparatus and method include those as disclosed in U.S. Pat. Nos. 3,278,663, 3,337,665, 3,456,044, 4,590,106, 4,760,116, 4,769,421, 4,797,235, and 4,886,634.

In one embodiment, a film or sheet which can be used for the weather-resistant layer (iii) is a PVF film or sheet comprising or consisting essentially of PVF, and the PVF is a thermoplastic fluoropolymer having —(CH₂CHF)ₙ— repeat units. It can be prepared by means of any suitable method, such as those disclosed in U.S. Pat. No. 2,419,010. According to the present disclosure, the PVF film or sheet can be prepared by means of any suitable method, such as casting or solvent-assisted extrusion. For example, U.S. Pat. No. 3,139,470 discloses a method for producing a PVF film.

The PVF film and sheet used herein is also commercially available, for example, Tedlar® PVF film available from E.I. du Pont de Nemours and Company, U.S., (hereinafter referred to as “DuPont”).

In another embodiment, the film or sheet used for the weather-resistant layer (iii) is a PVDF film or sheet comprising or consisting essentially of PVDF, and the PVDF is a thermoplastic fluoropolymer having —(CH₂CF₂)ₙ— repeat units. Commercially available PVDF films or sheets include, but are not limited to, a Kynar™ PVDF film from Arkema Inc., U.S., and a Denka DX film from Denka Group, Japan.

In addition, according to the present disclosure, the film or sheet comprising a fluoropolymer, as used herein, may further include those films or sheets having undergone various surface treatments for improving the bonding performance thereof to other films or sheets. Exemplary surface treatments include, but are not limited to, a chemical treatment (see, e.g., U.S. Pat. No. 3,122,445), a flame treatment (see, e.g., U.S. Pat. No. 3,145,242), and a discharge treatment (see, e.g., U.S. Pat. No. 3,274,088).

The present invention further provides a method for preparing the solar cell module back sheet, which comprises:

(1) providing a weather-resistant layer (iii) comprising a fluoropolymer, which has a front surface facing solar radiation and a back surface not facing the solar radiation when in use;

(2) applying an adhesive composition comprising a polyurethane to the front surface of the weather-resistant layer (iii) to form an adhesive layer (ii);

(3) providing the components (a), (b), (c), (d), (e) and (f) below:
(a) about 60 wt % to 98.74 wt % of a polyethylene selected from a linear low density polyethylene, a low density polyethylene, a high density polyethylene, and a mixture thereof;
(b) about 0.1 wt % to 2.5 wt % of a silane;
(c) about 1 wt % to 3 wt % of titanium oxide;
(d) about 0.05 wt % to 0.5 wt % of a peroxide;
(e) about 0.01 wt % to 0.05 wt % of a tin carboxylate; and
(f) about 0.1 wt % to 33.95 wt % of at least one additive selected from an inorganic filler excluding titanium oxide, an antioxidant, an anti-ultraviolet agent, a lubricant, and a mixture thereof,

the wt % being based on the total weight of the components (a), (b), (c), (d), (e) and (f);

(4) mixing the components (a), (b), (c), (d), (e) and (f) at a temperature of about 180-230° C. to obtain a silane cross-linked polyethylene composition;

(5) extruding and casting the silane cross-linked polyethylene composition obtained in step (4) to prepare a sheet comprising the silane cross-linked polyethylene composition; and

(6) compounding the above-mentioned sheet comprising the silane cross-linked polyethylene composition onto the adhesive layer (ii) to prepare the solar cell module back sheet.

In one embodiment, when mixing the components (a), (b), (c), (d), (e) and (f) in step (4), first, a polyethylene, titanium oxide, an antioxidant, an anti-ultraviolet agent, a lubricant, etc., are uniformly mixed, put into an extruder, melt-extruded and pelletized to prepare a first masterbatch; then, the polyethylene is further mixed uniformly with another inorganic filler, etc., put into an extruder, melt-extruded and pelletized to prepare a second masterbatch; and then the above-mentioned two masterbatches, a polyethylene, a silane, a peroxide, a tin carboxylate, etc., are mixed uniformly, put into an extruder and melt-extruded to obtain a silane cross-linked polyethylene composition.

According to the present invention, the method for applying the adhesive composition to the weather-resistant layer in step (2) includes, but is not limited to, roll coating, blade coating and spray coating; and after the application of the adhesive composition to the front surface of the weather-resistant layer to obtain a complex of the adhesive layer and the weather-resistant layer, the complex needs to be conveyed via a conveyor roller into a drying oven and dried at a temperature of about 50° C. to 100° C. for a time of about 1 minute to allow the solvent in the adhesive composition to sufficiently volatilize.

According to the present invention, prior to compounding the sheet comprising the silane cross-linked polyethylene composition onto the adhesive layer (ii) in step (6), the sheet comprising the silane cross-linked polyethylene composition firstly needs to be placed in a room-temperature or high-temperature environment to allow for a sufficient cross-linking reaction of the polyethylene; and then the complex obtained in step (2) and the sheet comprising the silane cross-linked polyethylene composition are separately sent to two conveyor rollers (preheated to about 60° C. to 80° C.) of a compounding apparatus, then conveyed to a compounding roller for compounding and then cooled. The compounding apparatus includes, but is not limited to, press rollers, calender rollers, and a plate hot press.

The present invention further provides a solar cell module comprising at least one solar cell, a back encapsulant layer and the above-mentioned back sheet, the solar cell having a front surface facing solar radiation and a back surface not facing the solar radiation when in use, and the back encapsulant layer being bonded to the back surface of the solar cell and the substrate of the back sheet.

The solar cell as used herein may be any photoelectric conversion device that can convert solar radiation into electrical energy. These device may be formed from a photoelectric converter, with electrodes being formed on two main faces thereof. The photoelectric converter can be manufactured from any suitable photoelectric conversion material such as crystalline silicon (c-Si), amorphous silicon (a-Si), microcrystalline silicon (μc-Si), cadmium telluride (CdTe), copper indium selenide (CuInSe₂ or CIS), copper indium/gallium diselenide (CulnₓGa₍₁₋ₓ₎Se₂ or CIGS), a light-absorbing dye, and an organic semiconductor. A front electrode can be formed from a conductive paste such as a silver paste, which paste is applied onto the front surface of the photoelectric converter by means of any suitable printing method, such as screen printing or inkjet printing. The front conductive paste may comprise a plurality of parallel conductive gate lines, and solder strips which are connected and perpendicular to the conductive gate lines make a current converge to a bus bar; in addition, a back electrode can be formed by printing a metal paste onto the entire back surface of the photoelectric converter. Suitable metals for forming the back electrode include, but are not limited to, aluminum, copper, silver, gold, nickel, molybdenum, cadmium, and alloys thereof.

In use, the solar cell generally has a front surface facing solar radiation and a back surface facing away from the solar radiation. Therefore, each component layer in the solar cell module has a front surface and a back surface.

According to the present disclosure, the back encapsulant layer comprises a polymeric material selected from polyolefins (PO), an ethylene vinyl acetate copolymer (EVA), or a mixture thereof, or preferably, the polymeric material comprised in the back encapsulant layer is EVA. EVA-based encapsulant layers suitable for the present invention are commercially available, for example, as EVASKY™ available from Bridgestone, Japan, Ultrapearl™ available from Sanvic Inc., Japan, BixCure™ available from Bixby International Corp., U.S., or Revax™ available from Wenzhou Ruiyang Photovoltaic Material Co., Ltd., and First™ available from Hangzhou First Applied Material Co., Ltd.

The solar cell module described herein may further include a transparent front encapsulant layer laminated to the front surface of the solar cell and a transparent front sheet further laminated to the front surface of the front encapsulant layer.

Suitable materials for the transparent front encapsulant layer include, but are not limited to, components comprising the following substances: EVA, ionomers, poly(vinyl butyral) (PVB), polyurethanes (PU), polyvinyl chloride (PVC), polyethylene, polyolefin block elastomers, ethylene/acrylate copolymers such as ethylene/methyl acrylate copolymers and ethylene/butyl acrylate copolymers, acid copolymers, siloxane elastomers, epoxy resins, and combinations thereof.

Any suitable glass or plastic sheet may be used as the transparent front sheet. Suitable materials for the plastic front sheet may include, but are not limited to, glass, polycarbonates, acrylic resins, polyacrylates, cyclic polyolefins, metallocene catalyzed polystyrenes, polyamides, polyesters, fluoropolymers, and combinations thereof.

The solar cell module disclosed herein can be manufactured using any suitable lamination method. In one embodiment, the method includes: (a) providing a plurality of electrically interconnected solar cells; (b) forming a pre-laminated assembly, wherein the solar cells are placed on the back encapsulant layer and then placed on the back sheet; and (c) laminating the pre-laminated assembly under heat and pressure. In another embodiment, the method includes: (a) providing a plurality of electrically interconnected solar cells; (b) forming a pre-laminated assembly, wherein the solar cells are sandwiched between the transparent front encapsulant layer and the back encapsulant layer, and then sandwiched between the transparent front sheet and the back sheet; and (c) laminating the pre-laminated assembly under heat and pressure.

As stated previously, it is desirable to develop a back sheet that is prepared by simple preparation steps, has lower material and manufacturing costs, and has excellent water resistance, insulation and mechanical properties. This object can be achieved by using the sheet comprising the silane cross-linked polyethylene composition of the present invention as the substrate of the back sheet. The inventors of the present invention have succeeded in reducing the number of holes in the plane of the sheet comprising the silane cross-linked polyethylene composition from 150/100 m² to zero or 1 or 2/100 m², and correspondingly, the mechanical properties (the longitudinal/transverse tensile strength, the longitudinal/transverse breaking elongation, the longitudinal/transverse tensile strength retention, and the longitudinal/transverse breaking elongation retention), electrical insulation (partial discharge voltage and breakdown voltage), water resistance (water transmission rate), and bonding to EVA encapsulating materials (peel strength) of the back sheet are all unexpectedly improved. In addition, not only does the back sheet of the present invention omit polyethylene terephthalate which is higher in cost and poorer in performance, the number of times it is necessary to apply an adhesive in the preparation process is reduced, making the preparation process simpler and more convenient.

Without further elaboration, it is believed that through the preceding description, a person skilled in the art would be able to make use of the present invention to the fullest extent thereof.

### Examples

The following examples are illustrative and do not unduly limit the scope of the present invention. The abbreviation “E” denotes “Example”, the abbreviation “CE” denotes “Comparative Example”, and the following number indicates in which example and comparative example a back sheet is prepared. All examples and comparative examples are prepared and tested in similar manners. Unless otherwise indicated, percentages are by weight.

### Materials

LLDPE: a linear low density polyethylene LL0220AA, available from Shanghai SECCO Petrochemical Company Limited;
HDPE: a high density polyethylene HD5502FA, available from Shanghai SECCO Petrochemical Company Limited;
Silane: vinyltriethoxysilane Silquest™ A-151, available from Momentive Performance Materials;
TiO₂: titanium oxide Ti-Pure™ R-105, available from Chemours, having an average particle size of 0.25 μm to 0.27 μm and a purity, with the surface being treated with a silane coupling agent, wherein the content of TiO₂ is 95%;
DCP: dicumyl peroxide, available from Sigma Aldrich, with CAS No.: 80-43-3;
DBTDL: dibutyltin dilaurate, available from Sigma Aldrich, with CAS No.: 77-58-7;
Antioxidant: pentaerythritol tetrakis[β-(3,5-di-tert-butyl-4-hydroxyphenyl)propionate] Irganox® 1010, available from BASF, with CAS No.: 6683-19-8;
Anti-UV agent: poly(4-hydroxy-2,2,6,6-tetramethyl-1-piperidineethanol)succinate Tinuvin™ 622, available from BASF, with CAS No.: 65447-77-0;
Lubricant: poly(vinylidene fluoride-co-hexafluoropropylene) Viton™ Freeflow™ Z210, available from Chemours, with CAS No.: 9011-17-0;
GF: ground glass fiber EMG10-35-106, available from Taishan Fiberglass Inc., with an average diameter of about 10 μm and an average length of about 35 μm;
Talc: talc powder HTP ultra 5L, available from IMI FABI, with an average particle size of about 1 μm;
SiO₂: silicon dioxide FB15D, available from Denka, which is spherical and has an average particle size of about 10 μm to 20 μm;
Adhesive composition: a mixed solution prepared from a polyurethane adhesive (CA022, available from DIC), a curing agent (TSH900, available from DIC) and ethyl acetate at a weight ratio of 18:1:14;
PVF film: a stretched polyvinyl fluoride film Tedlar® PV2025, available from DuPont, with a thickness of about 25 μm; and
EVA sheet: an ethylene vinyl acetate copolymer sheet First™ 806, available from Hangzhou First Applied Material Co., Ltd., with a thickness of about 500 μm.

### Preparation of Back Sheets of Examples E1-E10 and Comparative Examples CE1-CE3

The preparation of the back sheets of these examples and comparative examples is divided into the following two steps:

### 1. Preparation of a Substrate Comprising a Silane Cross-Linked Polyethylene Composition

With regard to Examples E1 and E2 and Comparative Examples CE2 and CE3: (1) first, about 9.4 wt % of polyethylene (based on the total weight of the polyethylene), titanium oxide, an antioxidant, an anti-ultraviolet agent and a lubricant are put into a high-speed stirrer (SUPER FLOATER SFC-50) and mixed uniformly, the mixture thereof is then put into a twin-screw extruder (Berstorff ZE25A), melt-extruded and pelletized, with the temperatures of 10 heating sections of the extruder being set to 80/200/200/200/200/200/200/200/200/200° C., the screw rotation speed being about 400 rpm and the extrusion yield being about 20 kg/h to 25 kg/h, and cooling and pellet sizing are carried out to obtain No. 1 masterbatch; and (2) then, the No. 1 masterbatch, a silane, a peroxide, a tin carboxylate, and the remaining about 90.6 wt % of polyethylene are added into the high-speed stirrer (SUPER FLOATER SFC-50) and mixed uniformly, the mixture is put into a single-screw extruder (Davis-Standard HPE 1.25) and melt-extruded, with the screw temperature being about 190° C. to 210° C. and the residence time of the mixed material to be extruded in the screw being 2 minutes to 5 minutes, the mixed material then enters a T-shaped die and is cast and extruded, with the die temperature being 200° C., and after cooling via a roller, pulling and edge cutting, with the pulling speed being controlled at 3 m/minute to 5 m/minute, a sheet comprising a silane cross-linked polyethylene composition is obtained. The amounts of the components in Examples E1 and E2 and Comparative Examples CE2 and CE3 are as shown in table 1.

With regard to Examples E3-E10: (1) first, about 9.4 wt % of polyethylene (based on the total weight of the polyethylene), titanium oxide, an antioxidant, an anti-ultraviolet agent and a lubricant are put into a high-speed stirrer (SUPER FLOATER SFC-50), mixed and homogenized, the mixture thereof is then put into a twin-screw extruder (Berstorff ZE25A), melt-extruded and pelletized, with the temperatures of 10 heating sections of the extruder being set to 80/200/200/200/200/200/200/200/200/200° C., the screw rotation speed being about 400 rpm and the extrusion yield being set to 20 kg/h to 50 kg/h, and cooling and pellet sizing are carried out to obtain No. 1 masterbatch; (2) then, about 5 wt % to 30 wt % of polyethylene (based on the total weight of the polyethylene) and an inorganic filler (such as ground glass fibers, talc or silicon dioxide) at a weight ratio of 1:1 are added to a mixer and mixed uniformly, the mixture thereof is then put into the twin-screw extruder, melt-extruded and pelletized, the screw temperature of the twin-screw extruder (Berstorff ZE25A) being set to about 200° C. and the screw rotation speed being 400 rpm, and cooling and pellet sizing are carried out to obtain No. 2 masterbatch; and (3) then, the No. 1 masterbatch, the No. 2 masterbatch, a silane, a peroxide, a tin carboxylate, and the remaining polyethylene are added into a high-speed stirrer, mixed and homogenized, the mixture thereof is then put into a single-screw extruder (Davis-Standard HPE 1.25) and melt-extruded, with the screw temperature being about 190° C. to 210° C., the screw rotation speed being about 100 rpm and the residence time of the mixed material to be extruded in the screw being about 2 minutes to 5 minutes, the mixed material then enters a T-shaped die, with the die temperature being about 200° C., and after cooling via a roller, pulling and edge cutting, with the pulling speed being controlled at 3 m/minute to 5 m/minute, a sheet comprising a silane cross-linked polyethylene composition is obtained. The amounts of the components in Examples E3-E10 are as shown in table 1.

With regard to Comparative Example CE1: (1) first, about 9.4 wt % of polyethylene (based on the total weight of the polyethylene), titanium oxide, an antioxidant, an anti-ultraviolet agent and a lubricant are added into a mixer, put into a high-speed stirrer (SUPER FLOATER SFC-50), mixed and homogenized, the mixture is put into a twin-screw extruder (Berstorff ZE25A), melt-extruded and pelletized, with the temperatures of the extruder being set to 80/200/200/200/200/200/200/200/200/200° C., the screw rotation speed being 400 rpm and the extrusion yield being set to 20 kg/h to 50 kg/h for the extruder, which includes 10 heating sections, and cooling and pellet sizing are carried out to obtain No. 1 masterbatch; and (2) then, the No. 1 masterbatch, a silane, a peroxide, a tin carboxylate, and the remaining about 90.6 wt % of polyethylene are added into the high-speed stirrer (SUPER FLOATER SFC-50), mixed and homogenized, the mixture is put into a single-screw extruder (Davis-Standard HPE 1.25) and melt-extruded, with the screw temperature being 190° C. to 210° C., the screw rotation speed being 100 rpm and the residence time of the mixed material to be extruded in the screw being 2 minutes to 5 minutes, the mixed material then enters a T-shaped die, with the die temperature being 200° C., and after cooling via a roller, pulling and edge cutting, with the pulling speed being controlled at 3 m/minute to 5 m/minute, a sheet comprising a silane cross-linked polyethylene composition is obtained. The amounts of the components in Comparative Example CE1 are as shown in table 1.

### 2. Preparation of a Back Sheet

First, the resulting sheet comprising the silane cross-linked polyethylene composition as mentioned above is left at 60° C. for 5 days, so that the polyethylene is sufficiently cross-linked; then, an adhesive composition is applied, by means of a roll coating method, onto the front surface of the weather-resistant layer to obtain a complex surface of an adhesive layer and the weather-resistant layer, with the glue coating amount being 8 g/m² to 10 g/m², and the complex is sent to a drying channel through a conveyor roller, and left for about 1 minute so that a solvent in the adhesive composition is sufficiently volatilized, the temperature of the drying channel having three zones, i.e., 60° C./70° C./80° C.; and finally, the dried complex and the sheet comprising the silane cross-linked polyethylene composition are separately sent to two conveyor rollers (preheated to about 60° C. to 80° C.) of a compounding apparatus, then conveyed to a compounding roller for compounding and then cooled to room temperature, and further left in an oven at a temperature of about 50° C. to 60° C. for about 3 days to 5 days to prepare a solar cell module back sheet.

### Test Methods

Number of holes: during extruding and casting for preparing the sheet comprising the silane cross-linked polyethylene composition, the number of holes in the plane thereof is monitored and counted, wherein a penetrable hollow with an area of greater than 0.01 cm² formed on the plane thereof due to the lack of silane cross-linked polyethylene composition is considered a hole, and the number of holes per 100 m² in the plane is denoted as the number of holes in units of number/100 m².
Tensile strength and breaking elongation: in accordance with GB/T13542.2-2009, the sheet comprising the silane cross-linked polyethylene composition or the back sheet in each of the examples and comparative examples is cut into a 200 mm long, 10 mm wide sample; the longitudinal tensile strength (in units of MPa) and the longitudinal breaking elongation (in units of %) thereof are measured by applying a load to the sample longitudinally (in the lengthwise direction) at a tensile speed of 100 mm/min until the sample breaks, the median value of the test values of 5 samples being taken as the test result; and the transverse tensile strength (in units of MPa) and the transverse breaking elongation (in units of %) thereof are measured by applying a load to the sample transversely (in the widthwise direction) at a tensile speed of 100 mm/min until the sample breaks, the median value of the test values of 5 samples being taken as the test result.
Tensile strength and breaking elongation retention: in accordance with GB/T2423.40, the back sheet of each of the examples and comparative examples is placed in an accelerated aging test machine and left for 48 hours, with the accelerated aging test machine having a temperature of about 121° C., a pressure of about 0.09 MPa to 0.11 MPa and a humidity of 100%; the sample is then taken out, and the longitudinal tensile strength, transverse tensile strength, longitudinal breaking elongation and transverse breaking elongation of the aged back sheet are measured according to the above-mentioned methods for measuring tensile strength and breaking elongation; the longitudinal tensile strength value of the aged back sheet is divided by the longitudinal tensile strength value of the back sheet before being aged and multiplied by a hundred percent to obtain the longitudinal tensile strength retention thereof (in units of %); the transverse tensile strength value of the aged back sheet is divided by the transverse tensile strength value of the back sheet before being aged and multiplied by a hundred percent to obtain the transverse tensile strength retention thereof (in units of %); the longitudinal breaking elongation of the aged back sheet is divided by the longitudinal breaking elongation value of the back sheet before being aged and multiplied by a hundred percent to obtain the longitudinal breaking elongation retention thereof (in units of %); and the transverse breaking elongation value of the aged back sheet is divided by the transverse breaking elongation value of the back sheet before being aged and multiplied by a hundred percent to obtain the transverse breaking elongation retention thereof (in units of %).

Peel strength: in accordance with GB/T 31034-2014, the back sheet in each of the examples and comparative examples is cut into a 250-300 mm long, 20 mm wide sample; and the back sheet sample, an EVA sheet and tempered glass having a thickness of about 3 mm are laid in bottom-to-top order (back sheet/EVA/glass), wherein the substrate of the back sheet is laminated to the EVA, placed in a vacuum laminating machine, laminated at 145° C. and under vacuum conditions for 10 minutes, and taken out after being cooled to room temperature, and a 180°-angle peel test is carried out using a pulling force testing machine at a tensile speed of 10 cm/min to obtain the peel strength between the back sheet and the EVA encapsulating material, in units of N/cm.

Water transmission rate: in accordance with GB/T 20263-2010, a test for the water vapor transmission rate (WVTR) of the back sheet of each of the examples and comparative examples is carried out, so that the amount of water vapor transmitted by a sample having a test area of 1 m² under the conditions of a temperature of about 38° C. and a relative humidity of about 90% within 24 hours, in units of g/(m² 24 h), is obtained.
Partial discharge voltage: in accordance with GB/T 7354-2003, the partial discharge voltage of the back sheet of each of the examples and comparative examples is measured, with a rate of voltage increase of about 20 V/s to 100 V/s, the median value of the tests of 10 samples being taken as the result, in units of kV.
Breakdown voltage: in accordance with GB/T 1408.1-2006, the breakdown voltage of the back sheet of each of the examples and comparative examples is measured, with a rate of voltage increase of 1000 V/s, the median value of the tests of 5 samples being taken as the result, in units of kV.
Reflectivity: the reflectivity of the back sheet of each of the examples and comparative examples is measured using a spectrophotometer within a wavelength coverage of 400 nm to 1100 nm, with incident light being incident from the surface of the substrate of the back sheet, the mean test value of 5 samples being taken as the result, in units of %.

Data about these properties of each of the examples and comparative examples as measured according to the above-mentioned methods are reported in Tables 1 and 2.

TABLE 1

| Component name | Unit | CE1 | CE2 | E1 | CE3 | E2 |
|---|---|---|---|---|---|---|
| LLDPE | wt % | 97.79 | 93.79 | 95.79 | | |
| HDPE | wt % | | | | 93.79 | 95.79 |
| Silane | wt % | 1.7 | 1.7 | 1.7 | 1.7 | 1.7 |
| TiO₂ | wt % | | 4.0 | 2.0 | 4.0 | 2.0 |
| DCP | wt % | 0.1 | 0.1 | 0.1 | 0.1 | 0.1 |
| DCPBL | wt % | 0.03 | 0.03 | 0.03 | 0.03 | 0.03 |
| Antioxidant | wt % | 0.17 | 0.17 | 0.17 | 0.17 | 0.17 |
| Anti-UV agent | wt % | 0.16 | 0.16 | 0.16 | 0.16 | 0.16 |
| Lubricant | wt % | 0.05 | 0.05 | 0.05 | 0.05 | 0.05 |
| Total part by weight | wt % | 100 | 100 | 100 | 100 | 100 |

Properties of sheet comprising silane cross-linked polyethylene

| | | | | | | |
|---|---|---|---|---|---|---|
| Number of holes | Number/ | 1 | 120 | 0 | 150 | 1 |
| | 100 m² | | | | | |
| Tensile strength - | MPa | 21.8/20.7 | 5.2/3.5 | 22.8/22.8 | 7.2/6.5 | 24.6/23.9 |
| Longitudinal/transverse | | | | | | |
| Breaking elongation - | % | 670/725 | 88/71 | 610/755 | 85/79 | 501/499 |
| Longitudinal/transverse | | | | | | |

Properties of back sheet

| | | | | | | |
|---|---|---|---|---|---|---|
| Tensile strength - | MPa | 20.1/19.2 | 17.1/17.2 | 18.1/18.2 | 16.0/16.3 | 19.0/19.3 |
| Longitudinal/transverse | | | | | | |
| Breaking elongation - | % | 125/130 | 89/80 | 121/120 | 80/82 | 103/102 |
| Longitudinal/transverse | | | | | | |
| Tensile strength retention - | % | | 86/86 | 85/85 | 80/81 | 82/83 |
| Longitudinal/transverse | | | | | | |
| Breaking elongation retention - | % | | 98/99 | 99/98 | 85/83 | 95/91 |
| Longitudinal/transverse | | | | | | |
| Peel strength | N/cm | | 58 | 60 | 44 | 49 |
| Reflectivity | % | 68 | 82.5 | 80.6 | 81.2 | 79.2 |
| Water transmission rate | g/(m² 24 h) | | 2.8 | 2.1 | 2.9 | 2.2 |
| Partial discharge voltage | kV | | 1.24 | 1.47 | 1.35 | 1.35 |
| Breakdown voltage | kV | | 22 | 21.8 | 21.0 | 21.0 |

Comparing the properties of the sheet comprising the silane cross-linked polyethylene composition of E1 with that of CE2, the number of holes in the sheet comprising the silane cross-linked polyethylene composition, which has a TiO₂ content of 4 wt %, in CE2 is 120/100 m², and by contrast, there are no holes in the sheet comprising the silane cross-linked polyethylene composition, which has a TiO₂ content of 2 wt % in E1. Compared with the properties of the sheet comprising the silane cross-linked polyethylene composition in CE2, the longitudinal tensile strength of the sheet comprising the silane cross-linked polyethylene composition in E1 is increased by 338%, the transverse tensile strength thereof is increased by 551%, the longitudinal breaking elongation thereof is increased by 593%, and the transverse breaking elongation thereof is increased by 963%.

Comparing the properties of the back sheet of E1 with those of that of CE2, as compared with the mechanical properties of the back sheet of CE2, the mechanical properties of the back sheet of E1 are unexpectedly improved, e.g., the longitudinal tensile strength is increased by 5.8%, the transverse tensile strength is increased by 5.8%, the longitudinal breaking elongation is increased by 36%, and the transverse breaking elongation is increased by 50%; even after accelerated aging, the tensile strength retention and breaking elongation retention of the back sheet of E1 are also equivalent to the corresponding tensile strength retention and breaking elongation retention of the back sheet of CE2. Compared with the water transmission rate of the back sheet of CE2, the water transmission rate of the back sheet of E1 is reduced by 25%, that is to say, the water resistance of the back sheet of E1 is unexpectedly improved. Compared with the partial discharge voltage and breakdown voltage of the back sheet of CE2, the partial discharge voltage of the back sheet of E1 is increased by 18.5%, the breakdown voltage of the back sheet of E1 also remains substantially unchanged, and the insulation of the back sheet of E1 is improved. Compared with the peel strength of the back sheet of CE2, the peel strength of the back sheet of E1 is increased by 3.4%, and the bonding of the back sheet of E1 to the EVA encapsulating material is improved.

Comparing the reflectivity of the back sheet of E1 and that of the back sheet of CE1, the reflectivity of the back sheet of CE1 is merely 68%, which cannot satisfy the requirement of same being greater than 70% in solar cell module back sheet applications, whereas the reflectivity of the back sheet of E1 is increased to 82.5%.

In one embodiment, in the solar cell module back sheet of the present invention, the silane cross-linked polyethylene composition is prepared by reacting the components (a), (b), (c), (d), (e) and (f) below:

(a) about 90 wt % to 98.74 wt % of a linear low density polyethylene;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 3.95 wt % of at least one additive selected from an antioxidant, an anti-ultraviolet agent, a lubricant, and a mixture thereof, wherein the wt % is based on the total weight of the components (a), (b), (c), (d), (e) and (f).

Likewise, comparing the properties of the sheet comprising the silane cross-linked polyethylene composition and the back sheet of E2 with those of the sheet comprising the silane cross-linked polyethylene composition and the back sheet of CE3, compared with the sheet comprising the silane cross-linked polyethylene composition of CE3, the number of holes in the plane of the sheet comprising the silane cross-linked polyethylene composition of E2 is reduced from 150/100 m² to 1/100 m², the longitudinal tensile strength thereof is increased by 242%, the transverse tensile strength thereof is increased by 268%, the longitudinal breaking elongation thereof is increased by 489%, and the transverse breaking elongation thereof is increased by 532%; compared with the mechanical properties of the back sheet of CE3, the mechanical properties of the back sheet of E2 are unexpectedly improved, e.g., the longitudinal tensile strength is increased by 18.8%, the transverse tensile strength is increased by 18.4%, the longitudinal breaking elongation is increased by 28.8%, and the transverse breaking elongation is increased by 24.3%; even after accelerated aging, the tensile strength retention and breaking elongation retention of the back sheet of E2 are also unexpectedly increased by 2.5% to 9.6% as compared with the back sheet of CE3; and compared with the water transmission rate of the back sheet of CE3, the water transmission rate of the back sheet of E2 is reduced by 24%, that is to say, the water resistance of the back sheet of E2 is unexpectedly improved. Compared with the partial discharge voltage and breakdown voltage of the back sheet of CE3, the partial discharge voltage and breakdown voltage of the back sheet of E2 remain substantially unchanged. Compared with the peel strength of the back sheet of CE3, the peel strength of the back sheet of E2 is increased by 11.4%, and the bonding of the back sheet of E2 to the EVA encapsulating material is improved.

In one embodiment, in the solar cell module back sheet of the present invention, the silane cross-linked polyethylene composition is prepared by reacting the components (a), (b), (c), (d), (e) and (f) below:

(a) about 90 wt % to 98.74 wt % of a high density polyethylene;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 3.95 wt % of at least one additive selected from an antioxidant, an anti-ultraviolet agent, a lubricant, and a mixture thereof, wherein the wt % is based on the total weight of the components (a), (b), (c), (d), (e) and (f).

TABLE 2

| Component name | Unit | E3 | E4 | E5 | E6 | E7 | E8 | E9 | E10 |
|---|---|---|---|---|---|---|---|---|---|
| LLDPE | wt % | 90.79 | 85.79 | 80.79 | 85.79 | 80.79 | 75.79 | 74.79 | 65.79 |
| Silane | wt % | 1.7 | 1.7 | 1.7 | 1.7 | 1.7 | 1.7 | 1.7 | 1.7 |
| TiO₂ | wt % | 2.0 | 2.0 | 2.0 | 2.0 | 4.0 | 2.0 | 4.0 | 2.0 |
| DCP | wt % | 0.1 | 0.1 | 0.1 | 0.1 | 0.1 | 0.1 | 0.1 | 0.1 |
| DCPBL | wt % | 0.03 | 0.03 | 0.03 | 0.03 | 0.03 | 0.03 | 0.03 | 0.03 |
| Antioxidant | wt % | 0.17 | 0.17 | 0.17 | 0.17 | 0.17 | 0.17 | 0.17 | 0.17 |
| Anti-UV agent | wt % | 0.16 | 0.16 | 0.16 | 0.16 | 0.16 | 0.16 | 0.16 | 0.16 |
| Lubricant | wt % | 0.05 | 0.05 | 0.05 | 0.05 | 0.05 | 0.05 | 0.05 | 0.05 |
| GF | wt % | 5.0 | 10.0 | 15.0 | | | | | |
| Talc | wt % | | | | 10 | 15 | 20 | | |
| SiO₂ | wt % | | | | | | | 21 | 30 |
| Total part by weight | wt % | 100 | 100 | 100 | 100 | 100 | 100 | 100 | 100 |

Properties of sheet comprising silane cross-linked polyethylene

| | | | | | | | | | |
|---|---|---|---|---|---|---|---|---|---|
| Number of holes | Number/ | 1 | 2 | 2 | 1 | 2 | 1 | 1 | 1 |
| | 100 m² | | | | | | | | |
| Tensile strength - | MPa | 24.1/23.3 | 20/20.1 | 19.2/17 | 22.3/21.1 | 23/22.1 | 19.4/19 | 20.7/21 | 19/19.4 |
| Longitudinal/transverse | | | | | | | | | |
| Breaking elongation - | % | 671/765 | 589/693 | 573/645 | 812/823 | 737/707 | 477/507 | 640/719 | 593/692 |
| Longitudinal/transverse | | | | | | | | | |

Properties of back sheet

| | | | | | | | | | |
|---|---|---|---|---|---|---|---|---|---|
| Tensile strength - | MPa | 20.1/19.9 | 19.9/19.5 | 18.6/18.5 | 21/20.2 | 22.1/19.1 | 20.9/20.5 | 17/17 | 17.8/17.9 |
| Longitudinal/transverse | | | | | | | | | |
| Breaking elongation - | % | 115/109 | 109/106 | 102/105 | 105/109 | 100/104 | 108/109 | 102/102 | 103/105 |
| Longitudinal/transverse | | | | | | | | | |
| Tensile strength | % | 95/94 | 98/97 | 112/109 | 95/98 | 97/96 | 99/98 | 95/94 | 95/94 |
| retention - | | | | | | | | | |
| Longitudinal/transverse | | | | | | | | | |
| Breaking elongation | % | 99/98 | 98/98 | 100/101 | 99/98 | 98/97 | 98/97 | 94/92 | 96/95 |
| retention - | | | | | | | | | |
| Longitudinal/transverse | | | | | | | | | |
| Peel strength | N/cm | 106 | 98 | 117 | 88 | 89 | 96 | 88 | 86 |
| Reflectivity | % | 78.2 | 77.2 | 76.8 | 77.9 | 77.8 | 77.3 | 78.7 | 78.9 |
| Water transmission rate | g/(m² 24 h) | 2.0 | 1.9 | 1.8 | 2.0 | 1.9 | 1.8 | 2.0 | 2.0 |
| Partial discharge voltage | kV | 1.4 | 1.42 | 1.39 | 1.4 | 1.41 | 1.38 | 1.41 | 1.38 |
| Breakdown voltage | kV | 22 | 23 | 23.1 | 22.5 | 22 | 22.1 | 22.9 | 21.8 |

Comparing the properties of E3-E5 with CE2, the number of holes in the sheets comprising the silane cross-linked polyethylene composition of E3-E5 is reduced from 120/100 m² to 1/100 m² or 2/100 m², and the longitudinal/transverse tensile strengths and the longitudinal/transverse breaking elongations thereof are all increased as compared with the sheet comprising the silane cross-linked polyethylene composition of CE2; compared with the mechanical properties of the back sheet of CE2, the mechanical properties of the back sheets of E3-E5 and the mechanical properties of same after being aged are also unexpectedly improved, e.g., the tensile strength retention after aging of the back sheet of E5 is significantly increased by 31.8% as compared with the back sheet of CE2 or E1; compared with the water transmission rate of the back sheet of CE2, the water resistance of the back sheets of E3-E5 are unexpectedly improved, e.g., the water transmission rate of the back sheet of E5 is reduced by 35.7%; compared with the partial discharge voltage and breakdown voltage of the back sheet of CE2, the partial discharge voltage and breakdown voltage of the back sheets of E3-E5 also remain substantially unchanged or are increased; and more unexpectedly, the bonding of the back sheets of E3-E5 to the EVA encapsulating materials are very significantly improved, e.g., compared with the peel strength of the back sheet of CE2, the peel strength of the back sheet of E5 is increased by 102%.

In one embodiment, in the solar cell module back sheet of the present invention, the silane cross-linked polyethylene composition is prepared by reacting the components (a), (b), (c), (d), (e) and (f) below:

(a) about 60 wt % to 95.74 wt % of a linear low density polyethylene;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 0.95 wt % of at least one additive selected from an antioxidant, an anti-ultraviolet agent, a lubricant, and a mixture thereof, and about 3 wt % to 33 wt % of glass fibers, the wt % being based on the total weight of the components (a), (b), (c), (d), (e) and (f).

Likewise, comparing E6-E10 with CE2, the number of holes in the sheets comprising the silane cross-linked polyethylene composition of E6-E10 is reduced from 120/100 m² to 1/100 m² or 2/100 m², and the longitudinal/transverse tensile strengths and the longitudinal/transverse breaking elongations thereof are all increased as compared with the sheet comprising the silane cross-linked polyethylene composition of CE2; and compared with the back sheet of CE2, the mechanical properties of the back sheets of E6-E10, the mechanical properties of same after being aged, the water resistance and electrical insulation thereof, and the bonding thereof to the EVA encapsulating materials are all unexpectedly improved.

In one embodiment, in the solar cell module back sheet of the present invention, the silane cross-linked polyethylene composition is prepared by reacting the components (a), (b), (c), (d), (e) and (f) below:

(a) about 60 wt % to 95.74 wt % of a linear low density polyethylene;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 0.95 wt % of at least one additive selected from an antioxidant, an anti-ultraviolet agent, a lubricant, and a mixture thereof, and about 3 wt % to 33 wt % of talc, the wt % being based on the total weight of the components (a), (b), (c), (d), (e) and (f).

In another embodiment, in the solar cell module back sheet of the present invention, the silane cross-linked polyethylene composition is prepared by reacting the components (a), (b), (c), (d), (e) and (f) below:

(a) about 60 wt % to 95.74 wt % of a linear low density polyethylene;

(b) about 0.1 wt % to 2.5 wt % of a silane;

(c) about 1 wt % to 3 wt % of titanium oxide;

(d) about 0.05 wt % to 0.5 wt % of a peroxide;

(e) about 0.01 wt % to 0.05 wt % of a tin carboxylate; and

(f) about 0.1 wt % to 0.95 wt % of at least one additive selected from an antioxidant, an anti-ultraviolet agent, a lubricant, and a mixture thereof, and about 3 wt % to 33 wt % of silicon dioxide, the wt % being based on the total weight of the components (a), (b), (c), (d), (e) and (f).

Although the present invention has been explained and described in the typical embodiments, this is not intended to limit the invention to the details as shown, because there may be various modifications and substitutions made without departing from the spirit of the present invention. Therefore, the modifications and equivalents of the present invention as disclosed herein would be obtained by a person skilled in the art only using conventional experiments, and it is considered that all such modifications and equivalents are within the spirit and scope of the present invention as defined by the following claims.

What is claimed is:

1. A back sheet for a solar cell module comprising:
(iv) a substrate comprising a silane crosslinked polyethylene composition;
(v) an adhesive layer comprising a polyurethane; and
(vi) a weather resistant layer comprising a fluoropolymer;
wherein:
the weather resistant layer (iii) has a front surface and a back surface, the front surface faces towards a light source when in use;
the adhesive layer (ii) is in contact with the substrate (i) and the front surface of the weather resistant layer (iii); and
the silane crosslinked polyethylene composition is derived from the reaction of components (a), (b), (c), (d), (e) and (f) as follows:
(g) 60 to 98.74 wt % of a polyethylene selected from the group consisting of linear low density polyethylene, high density polyethylene, low density polyethylene, and blends thereof;
(h) 0.1 to 2.5 wt % of a silane;
(i) 1 to 3 wt % of a titanium dioxide;
(j) 0.05 to 0.5 wt % of a peroxide;
(k) 0.01 to 0.05 wt % of a carboxylate of tin; and
(l) 0.1 to 33.95 wt % of at least one additive selected from the group consisting of inorganic fillers excluding titanium dioxide, anti-oxidant agents, anti-UV agents, lubricants, and mixtures thereof;
wherein the wt % is based on the total weight of the combined components.

2. The back sheet of claim 1, wherein the silane is selected from the group consisting of vinyltrimethoxy silane, vinyltriethoxy silane, vinyltris(2-methoxyethoxy) silane, 3-methacryloxypropyltrimethoxy silane, and mixtures thereof.

3. The back sheet of claim 1, wherein the peroxide is selected from the group consisting of dicumyl peroxide, benzoyl peroxide, t-butyl cumyl peroxide, di-t-butyl peroxide, and mixtures thereof.

4. The back sheet of claim 1, wherein the carboxylate of tin is selected from the group consisting of dibutyl tin dilaurate, dibutyltin laurate maleate, di-n-butyltin, stannous octoate, dibutyltin diacetate, and mixtures thereof.

5. The back sheet of claim 1, wherein the substrate (i) has a thickness of 100 to 500 μm, and has no hole or less than 15 holes per 100 m² on the surface of the substrate (i).

6. The back sheet of claim 1, wherein adhesive layer (ii) has a thickness of 5 to 20 μm, and the weather resistant layer (iii) has a thickness of 5 to 50 μm.

7. The back sheet of claim 1, wherein the inorganic fillers excluding titanium dioxide is selected from the group consisting of glass fibers, talcs, silica dioxides, micas, zinc sulfides, calcium carbonates, boron nitrides, clays, and mixtures thereof, and the weight of the inorganic fillers excluding titanium dioxide is 3 to 35 wt %, based on the total weight of the combined components.

8. The back sheet of claim 1, wherein the fluoropolymer is selected from homopolymers and copolymers of vinyl fluoride, vinylidene fluoride, tetrafluoroethylene, hexafluoropropylene, chlorotrifluoroethylene, and combinations of two or more thereof.

9. A solar cell module comprising at least one solar cell having a front surface and a back surface, a back encapsulant layer, and the back sheet of claim 1, wherein the back encapsulant layer is in contact with the back surface of the solar cell and the substrate (i) of the back sheet; and the front surface of solar cell faces towards a light source when in use.

10. The solar cell module of claim 9, wherein the back encapsulant layer comprises a polymeric material selected from ethylene vinyl acetate, polyolefin, and blends thereof.

11. A method for manufacturing a back sheet for a solar cell module comprising:
(7) providing a layer comprising a fluoropolymer as a weather resistant layer, which has a front surface and a back surface;
(8) applying a layer comprising a polyurethane to the front surface of the weather resistant layer to obtain an adhesive layer;
(9) providing components (a), (b), (c), (d), (e), and (f) as follows:
(a) 60 to 98.74 wt % of a polyethylene selected from the group consisting of linear low density polyethylene, high density polyethylene, low density polyethylene, and blends thereof;
(b) 0.1- to 2.5 wt % of a silane;
(c) 1 to 3 wt % of a titanium dioxide;
(d) 0.05 to 0.5 wt % of a peroxide;
(e) 0.01 to 0.05 wt % of a carboxylate of tin; and
(f) 0.1 to 33.95 wt % of at least one additive selected from the group consisting of glass fibers, talcs, silica dioxides, micas, zinc sulfides, calcium carbonates, boron nitrides, clays, anti-oxidant agents, anti-UV agents, lubricants, and mixtures thereof;
wherein the wt % is based on the total weight of the combined components;
(10) blending the components (a), (b), (c), (d), (e) and (f) at a temperature of 180 to 230° C. to obtain a blend;
(11) casting the blend of Step (4) to obtain a sheet comprising a silane crosslinked polyethylene composition; and
(12) laminating the sheet comprising a silane crosslinked polyethylene composition on top of the adhesive layer to obtain the back sheet.
